(19) United States
(12) Patent Application Publication
(10) Pub. No.: US 2012/0261663 A1
(43) Pub. Date: Oct. 18, 2012

(54) DISPLAY PANEL AND METHOD OF MANUFACTURING DISPLAY PANEL

(76) Inventor: Mitsuyuki Tsuji, Osaka-shi (JP)

(21) Appl. No.: 13/516,999

(22) PCT Filed: Dec. 1, 2010
(86) PCT No.: PCT/JP2010/071465

§ 371 Date: Jun. 18, 2012

(30) Foreign Application Priority Data
Dec. 21, 2009 (JP) 2009-288733

(51) Int. Cl. H01L 33/08; H01L 21/66

(52) U.S. Cl. 257/48; 438/18; 257/E33.012; 257/E21.531

(57) ABSTRACT

A display panel according to the present invention includes a first substrate including a first electrode portion and a connecting portion electrically connecting the first electrode portion to an external interconnection; a second substrate including a second electrode portion and disposed to face the first substrate; and a common transfer material electrically connecting the first electrode portion and the second electrode portion. The second electrode portion includes a detecting portion for detecting damage to the second substrate. The detecting portion is electrically connected to the first electrode portion and the external interconnection through the common transfer material. By the configuration as described above, it becomes possible to easily detect cracking, chipping and the like in the second substrate having no direct connection to the external interconnection.

### TECHNICAL FIELD

The present invention relates to a display panel and a method of manufacturing the display panel, and particularly to a display panel having an electrode portion for confirming whether or not there is damage to a substrate and a method of manufacturing the display panel.

### BACKGROUND ART

Japanese Patent Laying-Open No. 05-346587 (PTL 1) discloses a liquid crystal display element having a cracking detecting electrode disposed on a peripheral edge portion of a transparent substrate. PTL 1 discloses that the continuity test of the above-described cracking detecting electrode is performed to thereby allow electrical detection of breakage in the liquid crystal display element, so that the maintenance performance can be improved.

### CITATION LIST

### Patent Literature

### PTL 1: Japanese Patent Laying-Open No. 05-346587

### SUMMARY OF INVENTION

### Technical Problem

In recent years, due to a display panel having higher definition, a narrower frame and the like, it is increasingly necessary to provide an electrode for detecting “cracking”, “chipping” and the like in one of two facing substrates that does not have a terminal portion connected to an external interconnection (typically, a color filter substrate).

PTL 1 does not disclose a mechanism for allowing electrical conduction through the electrode for detecting “cracking”, “chipping” and the like in the substrate having no terminal portion.

The present invention has been made in light of the above-described problems. An object of the present invention is to provide a display panel capable of easily detecting “cracking”, “chipping” and the like in the substrate having no direct connection to an external interconnection, and a method of manufacturing the display panel.

### Solution to Problem

A display panel according to the present invention includes a first substrate including a first electrode portion and a connecting portion electrically connecting the first electrode portion to an external interconnection; a second substrate including a second electrode portion and disposed to face the first substrate; and a common transfer material electrically connecting the first electrode portion and the second electrode portion. The second electrode portion includes a detecting portion for detecting damage to the second substrate. The detecting portion is electrically connected to the first electrode portion and the external interconnection through the common transfer material.

It is to be noted that the damage to the substrate means that cracking, chipping, cracks and the like occur in the substrate.

According to one embodiment, in the above-described display panel, the detecting portion is formed so as to surround a prescribed region along an entire periphery thereof in the second substrate.

According to one embodiment, in the above-described display panel, the first electrode portion includes another detecting portion for detecting damage to the first substrate. Another detecting portion is disposed in a position where the connecting portion is not provided.

A method of manufacturing a display panel according to the present invention includes the steps of: preparing a first substrate including a first electrode portion and a connecting portion electrically connecting the first electrode portion to an external interconnection, and a second substrate including a second electrode portion; laminating the first substrate and the second substrate such that the first electrode portion and the second electrode portion are electrically connected through a common transfer material in a state where the first substrate and the second substrate face each other with the common transfer material interposed therebetween; and, after lamination of the first substrate and the second substrate, checking electrical conduction in the second electrode portion to confirm whether or not there is damage to the second substrate.

According to one embodiment, in the above-described method of manufacturing a display panel, electrical conduction in the second electrode portion is checked to confirm whether or not there is damage to the second substrate while electrical conduction in the first electrode portion is checked to confirm whether or not there is damage to the first substrate.

According to one embodiment, in the above-described method of manufacturing a display panel, the step of confirming whether or not there is damage to the second substrate is performed simultaneously with a lighting test of the display panel.

### Advantageous Effects of Invention

The present invention allows easy detection of “cracking”, “chipping” and the like in the second substrate having no direct connection to the external interconnection.

### BRIEF DESCRIPTION OF DRAWINGS

FIG. 1 is a diagram for schematically illustrating a method of detecting “cracking”, “chipping” and the like in a substrate in a display panel according to one embodiment of the present invention.

FIG. 2 is a diagram showing a specific example of the arrangement of an electrode portion (first substrate) in the display panel according to one embodiment of the present invention.

FIG. 3 is a diagram showing another specific example (first substrate) of the arrangement of the electrode portion in the display panel according to one embodiment of the present invention.

FIG. 4 is a diagram illustrating a common transfer material.

FIG. 5 is a diagram (first) showing a modification of the arrangement of the electrode portion.

FIG. 6 is a diagram (second) showing a modification of the arrangement of the electrode portion.

FIG. 7 is a diagram (third) showing a modification of the arrangement of the electrode portion.

FIG. 8 is a diagram (fourth) showing a modification of the arrangement of the electrode portion.

FIG. 9 is a diagram (fifth) showing a modification of the arrangement of the electrode portion.

FIG. 10 is a diagram (sixth) showing a modification of the arrangement of the electrode portion.

FIG. 11 is a diagram (seventh) showing a modification of the arrangement of the electrode portion.

FIG. 12 is a diagram (eighth) showing a modification of the arrangement of the electrode portion.

FIG. 13 is a diagram (ninth) showing a modification of the arrangement of the electrode portion.

### DESCRIPTION OF EMBODIMENTS

The embodiments of the present invention will be hereinafter described. The same or corresponding components are designated by the same reference characters, and description thereof may not be repeated.

In the embodiments described below, when the number, the quantity and the like are mentioned, the scope of the present invention is not necessarily limited thereto unless otherwise specified. In the following embodiments, each component is also not necessarily essential for the present invention unless otherwise specified.

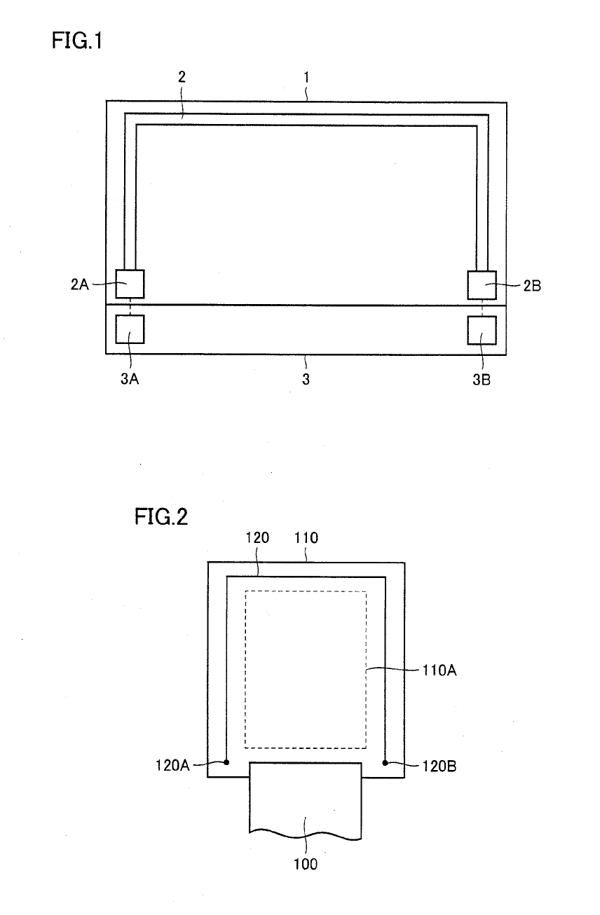

FIG. 1 is a diagram for schematically illustrating a method of detecting “cracking”, “chipping” and the like in a substrate in a display panel according to the present embodiment.

Referring to FIG. 1, the display panel according to the present embodiment includes a substrate 1 and an electrode portion 2.

As shown in FIG. 1, electrode portion 2 is formed on the peripheral edge portion of substrate 1 along the outer periphery of substrate 1. Electrode portion 2 is provided at its both ends with terminal portions 2A and 2B, respectively. In a typical example, at the time of the lighting test of the display panel, the panel is placed on an examining table 3, terminal portions 2A and 2B are electrically connected to terminal portions 3A and 3B, respectively, of a terminal table 3, to check the electrical conduction in electrode portion 2. In this case, when there are “cracking”, “chipping” and the like in the outer peripheral portion of substrate 1, electrode portion 2 is divided at this portion, which leads to inhibition of the electrical conduction in electrode portion 2. In this way, it can be determined whether or not there are “cracking”, “chipping” and the like in substrate 1.

Substrate 1 may be an array substrate (TFT substrate) or a color filter substrate in a liquid crystal display panel.

In the case where electrode portion 2 is formed in the above-mentioned array substrate, electrode portion 2 can be formed, for example, in conjunction with formation of a thin film transistor (TFT). In this way, electrode portion 2 can be formed without having to add a new step and a photomask.

On the other hand, in the case where electrode portion 2 is formed in the color filter substrate, electrode portion 2 can be formed, for example, in conjunction with formation of an ITO electrode for display. Instead, electrode portion 2 can be formed in conjunction with formation of a black matrix. Further instead, electrode portion 2 can also be formed by an ink jet technique.

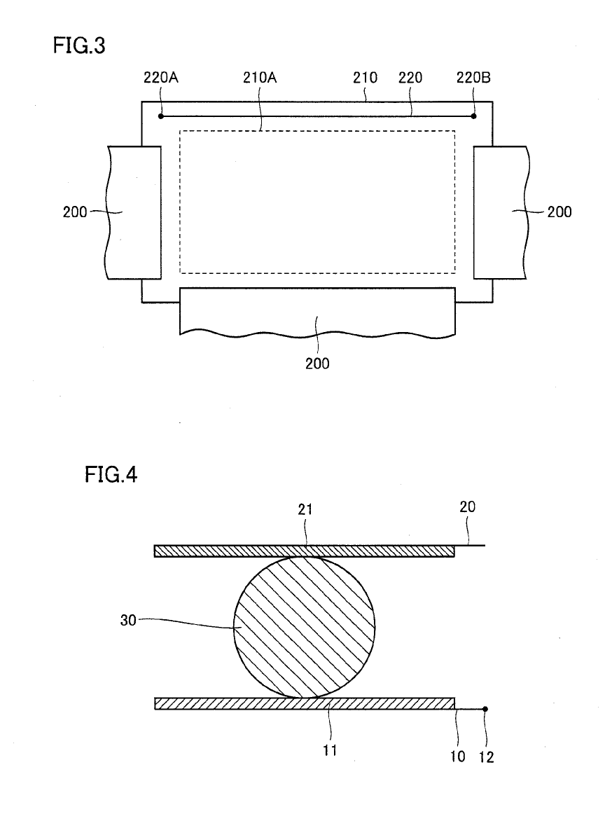

FIGS. 2 and 3 each are a diagram showing a specific example of the arrangement of the electrode portion. It is to be noted that the substrate shown in each of FIGS. 2 and 3 is typically an array substrate (TFT substrate).

For instance, in the example shown in FIG. 2, a flexible interconnection 100 is connected to a substrate 110, on which an electrode portion 120 is formed along the outer periphery of substrate 110. Electrode portion 120 is provided at its both ends with terminal portions 120A and 120B, respectively. Electrode portion 120 is formed on three sides of substrate 110 so as not to be located in the position where flexible interconnection 100 is connected.

Furthermore, in the example shown in FIG. 3, a flexible interconnection 200 is connected to a substrate 210, on which an electrode portion 220 is formed along the outer periphery of substrate 210. Electrode portion 220 is provided at its both ends with terminal portions 220A and 220B, respectively. Electrode portion 220 is formed only on one side of substrate 210 so as not to be located in the position where flexible interconnection 200 is connected.

In recent years, for the purpose of simplification of the interconnection and the like, the connecting portion (external terminal) connecting the external interconnection is disposed only on one of two facing substrates (in a typical example, only on the array substrate among the array substrate (TFT substrate) and the color filter substrate).

Detection of “cracking”, “chipping” and the like according to the present embodiment is characterized by a method of detecting “cracking”, “chipping” and the like in substrate 1 that does not have a connecting portion (external terminal) providing connection to the external interconnection, and specifically, characterized in that electrode portion 2 is brought into conduction through the common transfer material which will be described later.

Referring to FIG. 4, a first electrode portion 11 is formed on a first substrate 10 (typically, an array substrate (a TFT substrate)) while a second electrode portion 21 is formed on a second substrate 20 (typically, a color filter substrate). Second electrode portion 21 includes an electrode portion 2 as a “detecting portion” provided for detecting “cracking”, “chipping” and the like in second substrate 20. During use of the display panel, electrode portion 2 serves as a dummy electrode that does not have any particular function.

First electrode portion 11 and second electrode portion 21 are electrically connected through a common transfer material 30. A connecting portion 12 connected to the external interconnection is formed in first substrate 10. The external interconnection is electrically connected to first electrode portion 11 of first substrate 10 through connecting portion 12, and furthermore, electrically connected to second electrode portion 21 of second substrate 20 through common transfer material 30. This allows second electrode portion 21 on second substrate 20 to be connected to the external interconnection.

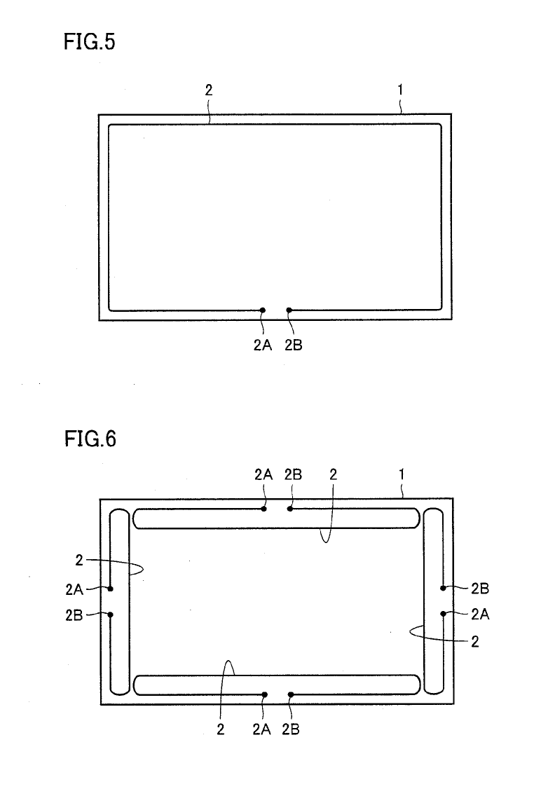

Then, referring to FIGS. 5 to 14, an example will be given with regard to the arrangement of electrode portion 2 formed on second substrate 20 for detecting “cracking”, “chipping” and the like.

As shown in FIGS. 5 to 14, on second substrate 20 (a TFT substrate and the like) having no connecting portion to the external interconnection, an electrode portion surrounding the substrate along its entire periphery can be formed.

In the example in FIG. 5, electrode portion 2 for detecting “cracking”, “chipping” and the like is provided along the entire outer periphery of substrate 1. Electrode portion 2 is provided at its both ends with terminal portions 2A and 2B, respectively.

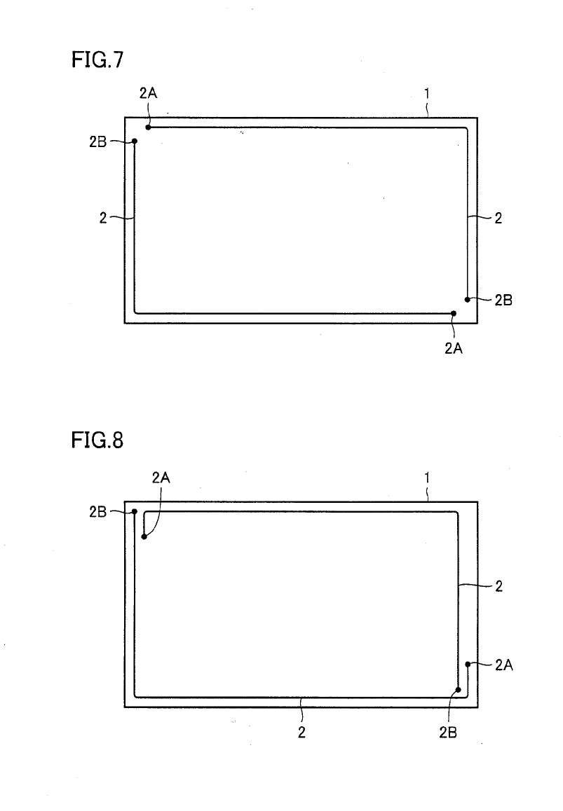

In the example shown in each of FIGS. 6 to 8, electrode portion 2 is divided into a plurality of sections. In other words, electrode portion 2 is divided into four sections in the example in FIG. 6 while electrode portion 2 is divided into two sections in the example in each of FIGS. 7 and 8. By dividing electrode portion 2 into a plurality of sections in this way, it becomes possible to easily find out the specific location in substrate 1 where “cracking”, “chipping” and the like exist.

In the example in FIG. 6, each electrode portion 2 has a dual structure consisting of a portion located on the outer peripheral side and a portion located on the inner peripheral side. This allows “cracking”, “chipping” and the like to be readily detected even when “cracking”, “chipping” and the like occur in a portion in substrate 1 corresponding to the space between terminal portions 2A and 2B.

In the example in each of FIGS. 7 and 8, electrode portion 2 is divided into a plurality of (two) sections, thereby providing terminal portions 2A and 2B. In the example in FIG. 8, electrode portions 2 are disposed on the outer peripheral side and the inner peripheral side, respectively, so as to overlap each other at terminal portions 2A and 2B. In this way, even in the case where “cracking”, “chipping” and the like occur in a portion in substrate 1 corresponding to the space between terminal portions 2A and 2B as in the example in FIG. 6, these “cracking”, “chipping” and the like can be readily detected.

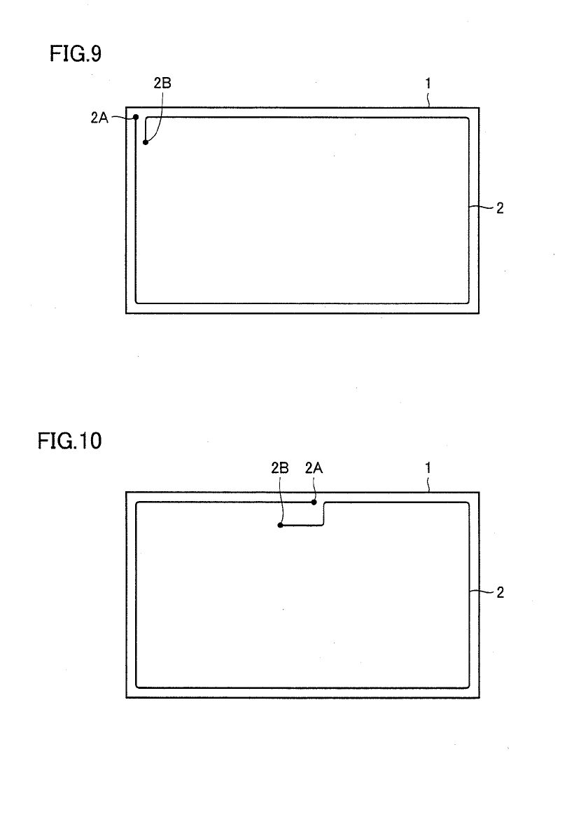

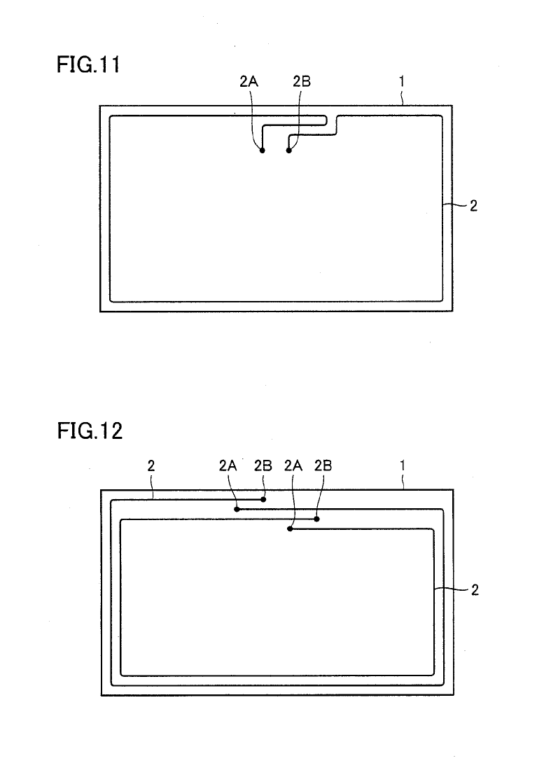

In addition, the arrangement of terminal portions 2A and 2B is not limited to that shown in each of FIGS. 5 to 8, but the arrangement as shown in each of FIGS. 9 to 11 can also be applicable. In the example shown in each of FIGS. 10 and 11, one electrode portion 2 surrounds substrate 1 along its entire periphery as in the example in FIG. 1.

In the example shown in FIG. 12, two electrode portions are disposed in substrate 1 on the inner peripheral side and the outer peripheral side. These electrode portions 2 are formed approximately parallel to each other. Also in the example in FIG. 12, “cracking”, “chipping” and the like in substrate 1 can be reliably detected.

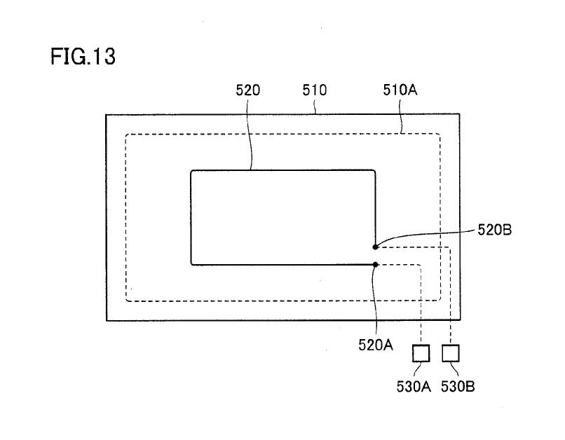

In the example shown in FIG. 13, electrode portion 2 for detecting “cracking”, “chipping” and the like is provided not in the peripheral edge portion of substrate 1 as in the examples in FIGS. 5 to 12, but in the region near the center portion of substrate 1.

In addition, electrode portion 2 has a width, for example, of approximately 1 mm or more and 3 mm or less. Furthermore, terminal portions 2A and 2B each have an approximately square shape, for example, of approximately 5 mm per side. Electrode portion 2 has a thickness, for example, of approximately 10 μm or more and 20 μm or less.

In addition, electrode portion 2 may be formed only on one side of substrate 1 or may be formed on both sides of substrate 1.

The above description will be summarized as follows. Specifically, the display panel according to the present embodiment includes first substrate 10 (for example, substrates 110 and 210 shown in FIGS. 2 and 3) including first electrode portion 11 (for example, electrode portions 120 and 220 shown in FIGS. 2 and 3) and connecting portion 12 electrically connecting first electrode portion 11 to the external interconnection (for example, flexible interconnections 100 and 200 shown in FIGS. 2 and 3); second substrate 20 including second electrode portion 21 and disposed to face first substrate 10; and common transfer material 30 electrically connecting first electrode portion 11 and second electrode portion 21. Second electrode portion 21 includes electrode portion 2 as a “detecting portion” for detecting damage to second substrate 20. Electrode portion 2 is electrically connected to first electrode portion 11 and the external interconnection through common transfer material 30.

In a typical example, although electrode portion 2 as a “detecting portion” is formed so as to surround a prescribed region along its entire periphery in the second substrate, the scope of the present invention is not necessarily limited thereto.

In a typical example, first electrode portion 11 (for example, electrode portions 120 and 220) includes a portion (another detecting portion) for detecting damage to first substrate 10 (for example, substrates 110 and 210). Although this portion is provided in the position where connecting portion 12 is not provided (see FIGS. 2 and 3), the scope of the present invention is not necessarily limited thereto.

The method of manufacturing a display panel according to the present invention includes the steps of: preparing first substrate 10 (for example, substrates 110 and 210) including first electrode portion 11 (for example, electrode portions 120 and 220) and connecting portion 12 electrically connecting this first electrode portion 11 to the external interconnection (for example, flexible interconnections 100 and 200), and second substrate 20 including second electrode portion 21; laminating first substrate 10 and second substrate 20 such that first electrode portion 11 and second electrode portion 21 are electrically connected through common transfer material 30 in the state where first substrate 10 and second substrate 20 face each other with common transfer material 30 interposed therebetween; and, after lamination of first substrate 10 and second substrate 20, checking electrical conduction in second electrode portion 21 to confirm whether or not there is damage to second substrate 20.

In a typical example, although the electrical conduction in second electrode portion 21 is checked to confirm whether or not there is damage to second substrate 20 while the electrical conduction in first electrode portion 11 is checked to confirm whether or not there is damage to first substrate 10, the scope of the present invention is not necessarily limited thereto.

Although the embodiments of the present invention have been described as above, it should be understood that the embodiments disclosed herein are illustrative and non-restrictive in every respect. The scope of the present invention is defined by the terms of the claims, and is intended to include any modifications within the scope and meaning equivalent to the terms of the claims.

### INDUSTRIAL APPLICABILITY

The present invention is applicable to a display panel and a method of manufacturing the display panel.

### REFERENCE SIGNS LIST

1, 110, 210 substrate, 2, 120, 220 electrode portion, 2A, 2B, 3A, 3B, 120A, 120B, 220A, 220B terminal portion, 2C recess, 3 examining table, 10 first substrate, 11 first electrode portion, 12 connecting portion, 20 second substrate, 21 second electrode portion, 30 common transfer material, 100, 200 flexible interconnection.

1-6. (canceled)

7. A display panel comprising:
a first substrate including a first electrode portion and a connecting portion electrically connecting said first electrode portion to an external interconnection;
a second substrate including a second electrode portion and disposed to face said first substrate; and
a common transfer material electrically connecting said first electrode portion and said second electrode portion,
said second electrode portion including a detecting portion for detecting damage to said second substrate, and
said detecting portion being electrically connected to said first electrode portion and said external interconnection through said common transfer material.

8. The display panel according to claim 7, wherein said detecting portion is formed so as to surround a prescribed region along an entire periphery thereof in said second substrate.

9. The display panel according to claim 7, wherein
said first electrode portion includes another detecting portion for detecting damage to said first substrate, and
said other detecting portion is disposed in a position where said connecting portion is not provided.

10. A method of manufacturing a display panel, comprising the steps of:
preparing a first substrate including a first electrode portion and a connecting portion electrically connecting said first electrode portion to an external interconnection, and a second substrate including a second electrode portion;
laminating said first substrate and said second substrate such that said first electrode portion and said second electrode portion are electrically connected through a common transfer material in a state where said first substrate and said second substrate face each other with said common transfer material interposed therebetween; and
after lamination of said first substrate and said second substrate, checking electrical conduction in said second electrode portion to confirm whether or not there is damage to said second substrate.

11. The method of manufacturing a display panel according to claim 10, wherein electrical conduction in said second electrode portion is checked to confirm whether or not there is damage to said second substrate while electrical conduction in said first electrode portion is checked to confirm whether or not there is damage to said first substrate.

12. The method of manufacturing a display panel according to claim 10, wherein said step of confirming whether or not there is damage to said second substrate is performed simultaneously with a lighting test of said display panel.
